(19) United States
(12) Patent Application Publication
(10) Pub. No.: US 2015/0282349 A1
(43) Pub. Date: Oct. 1, 2015

(54) EQUIPMENT RACK BRACING

(71) Applicant: International Business Machines Corporation, Armonk, NY (US)

(72) Inventors: Christopher W. Mann, Austin, TX (US); Tristan A. Merino, Austin, TX (US); Jason E. Minyard, Phoenix, AZ (US); Joni E. Saylor, Phoenix, AZ (US); Gregory S. Vande Corput, Rochester, MN (US)

(73) Assignee: International Business Machines Corporation, Armonk, NY (US)

(21) Appl. No.: 14/228,429

(22) Filed: Mar. 28, 2014

(51) Int. Cl. H05K 5/02; A47B 96/00; E05C 1/06

(52) U.S. Cl. CPC H05K 5/0217; E05C 1/06; A47B 96/00; H05K 5/0221; H05K 5/0239

(57) ABSTRACT

A brace assembly for an electronic equipment enclosure which may include a door is disclosed. The brace assembly may include a frame, a plurality of deadbolt assemblies and a plurality of catch rails. The frame may enclose a plurality of rigidly attached cross-members, and may fit within a perimeter of the door and attach to a face of the door. The plurality of deadbolt assemblies may be attached to the frame, and each deadbolt assembly may include a deadbolt. The plurality of catch rails may be configured to attach to the electronic equipment enclosure, and the catch rails may have recesses defined to receive a plurality of deadbolts when the door is in a closed position, and the deadbolts are in a latched position, thereby providing seismic bracing.

### TECHNICAL FIELD

The present disclosure relates to bracing for equipment racks. In particular embodiments, this disclosure relates to toolless bracing structures which may be used to stabilize electronic equipment racks and enclosures during seismic events.

### BACKGROUND

Equipment cabinets or racks may be used to contain servers, computer systems, telecommunications equipment and other information technology (IT) devices that may be used by businesses. Equipment cabinets may be provided in relatively tall and narrow configurations, and may house vertically stacked equipment to conserve floor space. For example, one standard cabinet configuration may be approximately 72 inches tall by approximately 22 inches wide.

Equipment cabinets may include front and rear doors which may provide the cabinets with a uniform appearance, protect devices housed within the cabinets from environmental hazards, restrict unauthorized access to the devices, and limit electromagnetic emissions from equipment within the cabinets. Front and rear doors may be attached to cabinets by hinges, and may be held in a closed position by a latching mechanism.

A server housed within an equipment cabinet may be a system (software and suitable computer hardware) that responds to requests across a computer network to provide, or assist in providing a network service. A server may be used to supply data to a number of clients on a private network or across the Internet, and may house a large volume of valuable and sensitive data.

### SUMMARY

Various aspects of the present disclosure may be useful for integrating bracing into an electronic equipment enclosure. A bracing structure configured according to embodiments of the present disclosure may control bowing, swaying, and axial rotation of an electronic equipment enclosure during a seismic event such as a tremor or earthquake.

Embodiments may be directed towards a seismic brace assembly for an electronic equipment enclosure that includes a door. The seismic brace assembly may include a frame, a plurality of deadbolt assemblies, and a plurality of catch rails. The frame may enclose a plurality of rigidly attached cross-members, and the frame may fit within a perimeter of the door and to attach to a face of the door. The plurality of deadbolt assemblies may be attached to the frame, and each deadbolt assembly may include a deadbolt. The plurality of catch rails may be grossly defined to receive a plurality of deadbolts when the door is in a closed position and the deadbolts are in a latched position, thereby providing seismic bracing.

Embodiments may also be directed towards an electronic equipment enclosure. The electronic equipment enclosure may include a cabinet which may have a first side surface and a second side surface opposite to the first side surface, where the first and second side surfaces define a cavity for housing an electronic component. The cabinet may also have a first mounting rail adjacent to the first side surface, and a second mounting rail adjacent to the second side surface, where the first and second mounting rails are configured to support the electronic component. The cabinet may also have a first door opening between a first vertical edge of the first side surface and a first vertical edge of the second side surface, where the door opening may receive a door in a closed position. The cabinet may also have a first door, pivotally attached to a vertical side of the door opening, and having mounting structures to receive a first frame. The cabinet may also have a first seismic brace assembly. The first seismic brace assembly may include the first frame, enclosing a plurality of rigidly attached cross-members, which may fit within a perimeter of the first door and to attach to a face of the first door. The first seismic brace assembly may also include a plurality of deadbolt assemblies attached to the first frame, each deadbolt assembly including a deadbolt. The first seismic brace assembly may also include a plurality of catch rails configured to attach to the electronic equipment enclosure. The catch rails may have recesses defined to receive a plurality of deadbolts when the first door is in a closed position and the deadbolts are in a latched position, and may thereby provide seismic bracing.

Embodiments may also be directed towards a seismic bracing kit for an electronic equipment enclosure that includes a door. The seismic bracing kit may include a frame, a plurality of deadbolt assemblies, and a plurality of catch rails. The frame may enclose a plurality of rigidly attached cross-members and, when assembled, may fit within a perimeter of the door and attach to a face of the door. The plurality of deadbolt assemblies may be attached to the frame, and each deadbolt assembly may include a deadbolt. The plurality of catch rails may be configured to be attached to the electronic equipment enclosure. The catch rails may have recesses defined to receive a plurality of deadbolts when the door is in a closed position and the deadbolts are in a latched position, and may thereby providing seismic bracing.

Aspects of the various embodiments may be used to help maintain structural integrity of electronic equipment enclosures during seismic events. Aspects of the various embodiments may also be useful for providing cost-effective seismic bracing for use with electronic equipment enclosures, by using existing and proven mechanical design and simulation practices, and machining and fabrication technologies.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is an isometric drawing of an electronic equipment enclosure, including a door having a seismic brace assembly, according to embodiments of the present disclosure.

FIG. 2 is an isometric drawing of an electronic equipment enclosure, including a door, in an open position, having a seismic brace assembly, according to embodiments.

FIG. 3 is an isometric drawing depicting an electronic equipment enclosure door, a frame, deadbolt assemblies and corresponding catch rails, according to embodiments.

FIG. 4 is an inset drawing depicting engagement of deadbolt assemblies with catch rails, according to embodiments.

FIG. 5 is an inset drawing depicting a deadbolt locking pin engaged in a deadbolt, according to embodiments.

FIG. 6 is an exploded diagram illustrating the integration of a seismic brace assembly into an electronic equipment enclosure, according to embodiments.

FIG. 7 is a top view of an electronic equipment enclosure door, and a frame of a seismic brace assembly, in a closed and two open positions, according to embodiments.

FIG. 8 is a top view of an electronic equipment enclosure door, and a seismic brace assembly, including a deadbolt assembly and a handle, according to embodiments.

FIG. 9 is an inset drawing depicting a catch rail designed to allow normal operation of an electronic equipment enclosure door hinge, according to embodiments.

FIG. 10 is an inset drawing depicting a catch rail designed to allow normal operation of an electronic equipment enclosure door latch mechanism, according to embodiments.

FIG. 11 includes views of 4 seismic brace assembly frame designs, according to embodiments.

FIG. 12 depicts a plurality of deadbolt assemblies connected through linkages to a common handle, according to embodiments.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

In the drawings and the Detailed Description, like numbers generally refer to like components, parts, steps, and processes.

### DETAILED DESCRIPTION

Certain embodiments of the present disclosure can be appreciated in the context of providing enhanced rigidity, during seismic events, to electronic equipment enclosures for electronic devices such as servers, storage devices or switches, which may be used to provide data to clients attached to a server through a network. Such servers may include, but are not limited to web servers, application servers, mail servers, and virtual servers. While not necessarily limited thereto, embodiments discussed in this context can facilitate an understanding of various aspects of the disclosure. Certain embodiments may also be directed towards other equipment and associated applications, such as providing enhanced rigidity, during seismic events, to electronic equipment enclosures housing devices such as computing systems, which may be used in a wide variety of computational and data processing applications. Such computing systems may include, but are not limited to, supercomputers, high-performance computing (HPC) systems, and other types of special-purpose computers. Embodiments may also be directed towards reinforcement for electronic equipment enclosures to facilitate enclosure structural integrity during shipment of populated electronic equipment enclosures.

Various embodiments of the present disclosure relate to a (seismic) bracing assembly configured to be mechanically engaged, without requiring the use of tools or specialized skills, with an electronic equipment enclosure. For ease of discussion, the term seismic is used herein, however, it is understood that various embodiments can also be useful with regards to other vibration sources. The seismic bracing assembly may be therefore be useful for providing consistent seismic bracing of electronic equipment enclosures during seismic events. Structurally stable and reliable performance of an electronic equipment enclosure may result from the use of a seismic bracing assembly. The seismic bracing assembly may help to preserve structural integrity of an electronic equipment enclosure while allowing access to equipment and cabling within the enclosure, and not interfering with the operation of an enclosure door or with airflow through the enclosure. Enhanced structural integrity provided by the seismic brace assembly may prevent damage to electronic equipment contained in the enclosure resulting from seismic events.

A seismic bracing assembly designed according to certain embodiments may be compatible with existing and proven electronic equipment enclosures and other facility-level and rack-level bracing solutions, and may be a useful and cost-effective way to protect electronic equipment enclosures from permanent damage. A seismic bracing assembly constructed according to embodiments of the present disclosure may be installed on an existing electronic equipment enclosure.

Electronic equipment such as computing systems, servers, and telecommunications equipment may be housed in electronic equipment enclosures, also known as racks or cabinets, which may be installed in data centers. Data centers may be subject to damage and loss of operations after seismic events such as tremors and earthquakes. An equipment rack may contain, for example, electronic components having a total weight of as much as 3,000 pounds, and may shift and/or topple during seismic activity, which may risk human injury, permanent loss of sensitive and valuable data, hardware damage, and extensive system downtime. Data centers located in seismic at-risk areas may be outfitted with hardware designed to withstand and reduce damage from seismic activity.

Hardware solutions available to mitigate data center seismic damage may be implemented is at a facility level, or a rack level. A facility-level solution may include mechanically connecting one or more equipment enclosures to a facility structure. For example, enclosures may be connected to overhead bracing, which may secure enclosures to a data center building's ceiling structure. Seismic bracing kits that tie the bottom of a rack to a building's floor structure may also be installed, and both ceiling and floor bracing methods may be used in conjunction with rack-level bracing to provide increased seismic stability of equipment enclosures. Facility-level systems may require a significant capital investment and specialized installation expertise, which may make them less practical for some data centers or central office locations.

A rack-level seismic solution may be completely contained within the electronic equipment enclosure. For example, add-on seismic framing kits may be bolted directly to an equipment enclosure, internal to the front and/or rear rack doors. The added rigidity from add-on seismic framing kits may prevent cabinets from swaying apart during a seismic event.

The installation of add-on seismic framing kits may require the use of tools, and may require a moderate amount of time to install, for example, approximately 20 minutes. Seismic framing kits may block access to rack-mounted devices (e.g., servers) during regular service and maintenance operations. The time and effort needed to uninstall and reinstall such kits in conjunction with rack system configuration (e.g., replacing a server or computation unit), may result in the kits not being or remaining installed consistently. The unpredictable nature of seismic events, combined with inconsistent bracing kit installation may result in equipment enclosures remaining vulnerable to damage resulting from seismic events. Seismic framing kits may also limit future hardware from extending forward from standard Electronic Industries Alliance (EIA) mounting rails.

Another type of rack-level solution may include the use of welded seismic racks having structural bracing features integrated into the sidewalls of the rack. This type of rack-level solution may have the benefit of not interfering with front access to rack mounted devices, but may interfere with side cabling or side-mounted devices such as power distribution units. These types of solutions may also make it difficult to achieve Network Equipment-Building System (NEBS) 3 and seismic Zone 4 certification at higher system weights, as the bracing may not be installed at the front and rear of the rack, which may leave the rack vulnerable to side-side sway. The lack of front and rear bracing structures may limit the electronic equipment weight capacities of rack systems. For example, a rack system not including front and rear bracing may have a weight limit of approximately 1,000 pounds. Welded seismic racks may be a specialty item, and may present cost disadvantages for businesses, when compared to the cost of standard rack enclosure designs.

Particular embodiments of the present disclosure may be useful for converting an electronic equipment enclosure that they not pass seismic certification testing into an enclosure that may be seismically certified. The addition of one or more seismic bracing structures, for example, as seismic bracing kits, may be useful to enable a formerly non-seismically certified electronic equipment enclosure to pass seismic certification testing, for example, NEBS 3 and seismic Zone 4 tests.

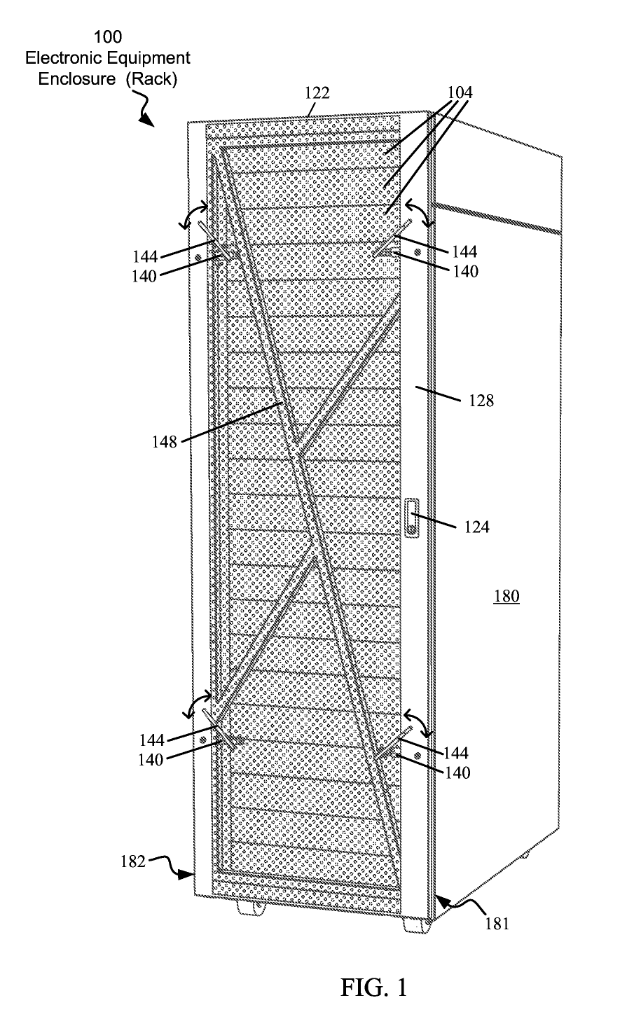

Certain embodiments relate to rack-level seismic reinforcement of an electronic equipment enclosure by the engagement, through the use of deadbolts, of a seismic brace assembly with the enclosure. Rack-level seismic reinforcement solutions may be used alone or in conjunction with facility-level seismic solutions. FIG. 1 is an isometric drawing of an electronic equipment enclosure (rack) 100, including a closed door 122 having a seismic brace assembly generally useful for reinforcing the enclosure, according to embodiments of the present disclosure. A seismic brace assembly may include a frame 148, deadbolt assemblies 140, and catch rails to engage with the deadbolt assemblies, according to embodiments.

Electronic equipment enclosure (rack) 100 may have industry-standard dimensions, for example, 19 inch or 23 inch wide openings for electronic components 104, and 42U or 47U standard heights, and may be used to house electronic components 104, which may be server, computer, telecommunications or other types of electronic equipment. A first side surface 180 and a second side surface (opposite to the first side surface 180) may define a cavity for housing electronic components 104 (top, bottom and back sides may also define the cavity). Rack 100 may include a (first) internal mounting rail adjacent to the first side surface 180, and a (second) mounting rail adjacent to the (second) side surface, opposite to surface 180, that are configured to support an electronic component 104, such as a server or computer processor. Rack 100 may include several such pairs of mounting rails arranged to support the electronic components 104, according to embodiments.

Rack 100 may have a (first) an opening for receiving the door between a first vertical edge 181 of the first side surface 180 and a second vertical edge 182 of the second side surface (opposite to 180). The (first) door opening may receive the door 122 in a closed position. The door 122 may be hinged (pivotally attached) to a vertical side of the (first) door opening near the second vertical edge 182 and may have a door latch mechanism 124, which may be used to secure and/or lock the door in a closed position. Door 122 may include materials such as perforated sheet metal, which may be useful for both electromagnetic interference (EMI) shielding and to allow cooling air to flow through the rack 100. Door 122 may be used to give the rack 100 a uniform appearance, and to secure the contents of the rack 100 from unauthorized access.

Door 122 may include a (first) attached frame 148, which may be a part of the seismic brace assembly, and may be particularly useful as a rigid add-on structure to help prevent bowing, warping and axial rotation of equipment rack 100 during seismic event, according to embodiments. Deadbolt assemblies 140, each including a deadbolt, may be attached to the (first) frame 148, and may be actuated by movement of operatively coupled deadbolt handles 144. In embodiments, deadbolt handles 144 may be located exterior to an outer face 128 of the door 122, for ease of access. Actuation of deadbolt assemblies 140 to a latched or an unlatched position, to engage with a first side portion 180 and a second side (opposite to 180) portion of the electronic equipment enclosure 100, may involve translation of handle 144 rotation into linear movement of a deadbolt, and may be useful for rapid mechanical engagement and disengagement of the frame 148 with rack 100, without involving the use of tools or assembly skills.

In certain embodiments, deadbolts may also be configured to engage with a top portion and a bottom portion of the electronic equipment enclosure, which may yield increased seismic stability relative to other embodiments. For example, certain embodiments may have 4 deadbolts that may be engaged with the sides of the door opening, and 4 deadbolts that may be engaged with the top and bottom of the door opening.

In certain embodiments, an electronic equipment enclosure 100, reinforced by a seismic brace assembly comprising a frame 148, deadbolt assemblies 140, and catch rails to engage with the deadbolt assemblies, may be suited to hold equipment weighing up to 2,000 pounds, and in some embodiments, may also be suited to withstand Seismic Zone 4 events.

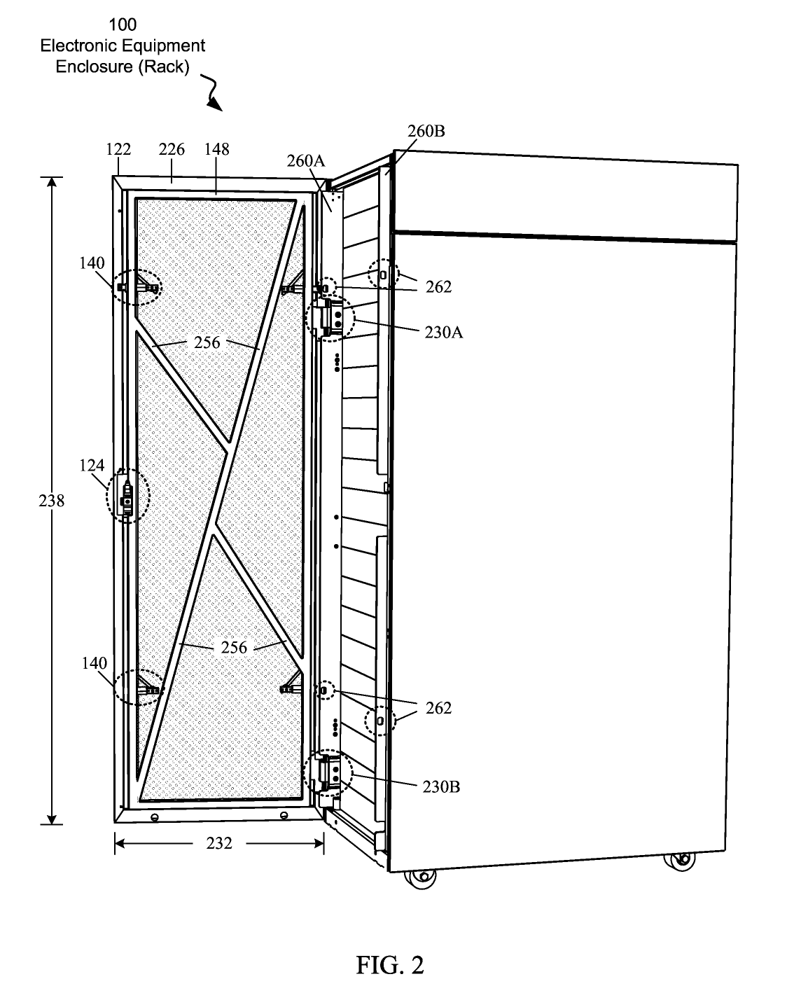

FIG. 2 is an isometric drawing of an electronic equipment enclosure 100, consistent with FIG. 1, including a seismic brace assembly and the door 122 in an open position. The seismic brace assembly may include a first frame 148 enclosing rigidly attached cross-members 256, deadbolt assemblies 140, and catch rails 260A and 260B attached to rack 100, according to embodiments. The frame 148 may have a planar, rectangular outline and may be attached to an inner face 226 of the (first) door 122 by fasteners such as screws or bolts. The frame may be attached to door 122 through the use of mounting structures (e.g., threaded holes) designed into door 122, according to embodiments.

The attachment of frame 148 to door 122 may be useful in allowing frame 148 to be moved with door 122 to an open position, where it may not restrict access to electronic components or wiring within electronic equipment enclosure 100.

Door height 238 and door width 232 may define a perimeter of the door 122, and the frame 148 may be designed to fit within the perimeter, which may prevent frame 148 from obstructing the closure of door 122 against the enclosure 100. The door 122 may be hinged (pivotally attached) using hinges 230A, 230B to rack 100, and may held and/or locked in a closed position by a door latch mechanism 124. Hinges 230A, 230B may allow door 122 to be removed from rack 100.

The frame 148 may include passageways, corresponding to the positions of the deadbolts 140, which may allow movement of the deadbolts through the frame 148. When the (first) door 122 is in a closed position, and a deadbolt assembly 140 is in a latched position, the deadbolts may be received by recesses 262 in the catch rails 260A, 260B, mechanically engaging the seismic brace assembly with the rack 100, which may be useful to provide seismic bracing to the rack 100, according to embodiments.

Electronic equipment enclosure 100 may have a second door opening opposite to the first door opening, for example, in the rear of the enclosure, and a second door opposite to the first door, with the second door having a second seismic brace assembly, similar to the first door's seismic brace assembly. The second frame may enclose a plurality of rigidly attached cross-members, to fit within a perimeter of the second door, and a plurality of deadbolt assemblies attached to the second frame, consistent with the first frame.

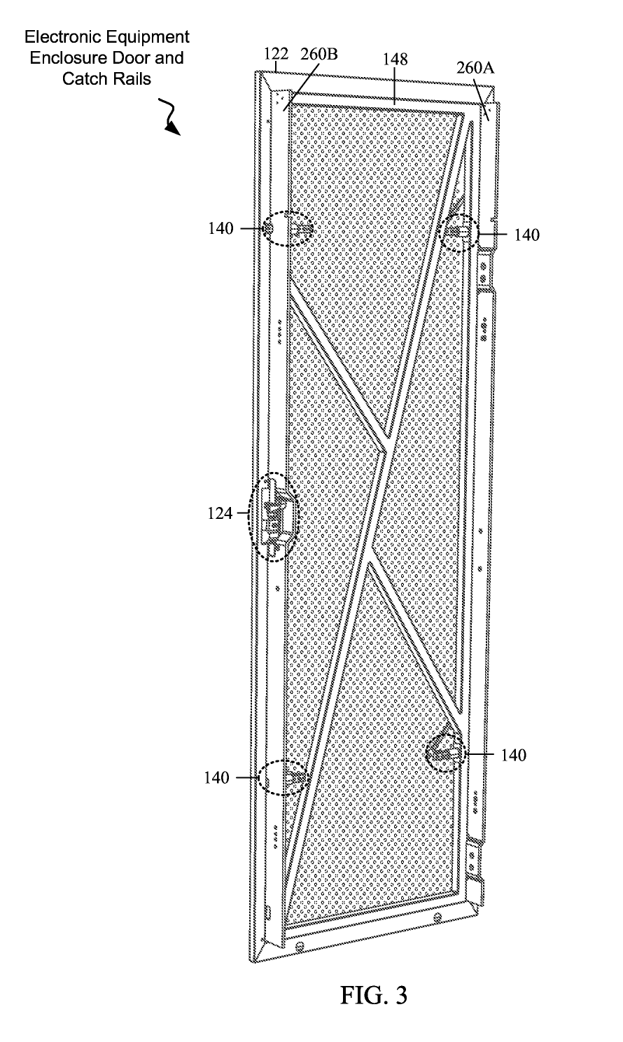

FIG. 3 is an isometric drawing consistent with FIG. 2, depicting the electronic equipment enclosure door 122, the frame 148, deadbolt assemblies 140 and corresponding catch rails 260A, 260B, according to embodiments. FIG. 3 depicts catch rails 260A, 260B positioned in an orientation, relative to door 122, similar to one that they would be in when installed in the enclosure 100, with door 122 in a closed position (FIG. 1). FIG. 3 may be useful in illustrating relative positioning and interaction of door 122, frame 148, deadbolt assemblies 140 and catch rails 260A, 260B. In the orientation depicted, deadbolts of deadbolt assemblies 140 may be aligned with recesses in catch rails 260A, 260B, and may pass through the recesses when the deadbolt assemblies 140 are in a latched position and door 122 is in a closed position (FIG. 1). The engagement of the deadbolts with the catch rails, which may be attached to rack 100 (FIG. 2), may be useful in providing a rapid, toolless way of mechanically connecting frame 148 to rack 100 (FIG. 1, 2), thereby providing seismic bracing to rack 100.

Frame 148 may include passageways, defined by positions of the deadbolts, which may allow movement of the deadbolts through the frame, to be received by the recesses in the catch rails. Catch rail 260B includes a bend that may allow clearance for the door latch mechanism 124 to be operated without interference from catch rail 260B.

Frame 148 of the seismic brace assembly may have a height and width sufficiently small to fit within the perimeter of the door 122, and may not prevent or obstruct door 122 from closing completely against rack 100 (FIG. 1). Deadbolts of deadbolt assemblies 140 may be configured to engage with upper and lower portions of each of the catch rails 260A, 260B, which may be positioned adjacent to the (first and second) side surfaces 180 (FIG. 1) of the electronic equipment enclosure 100 (FIG. 1).

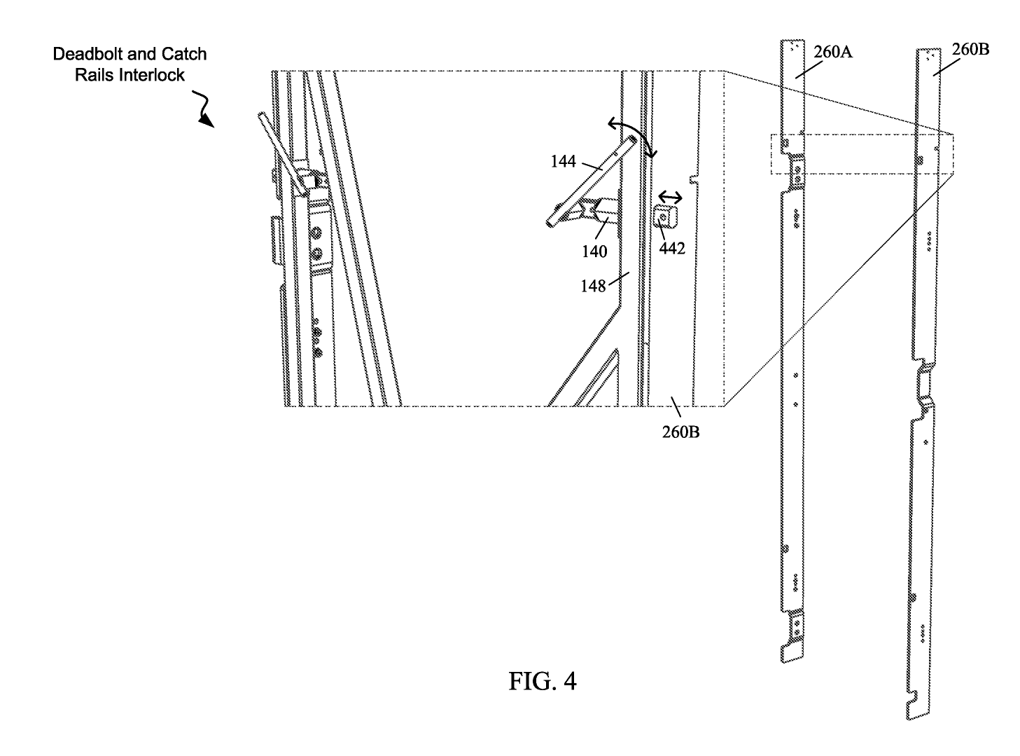

FIG. 4 is an inset drawing consistent with FIG. 3, depicting engagement of deadbolt assemblies 140, with catch rails 260A, 260B, according to embodiments. FIG. 4 depicts deadbolt 442 of deadbolt assembly 140 passing through a passageway in frame 148, and through a recess in catch rail 260B, in a latched position. Handle 144 may be used to actuate deadbolt 442 to a latched or an unlatched (not engaged with catch rail 260B) position.

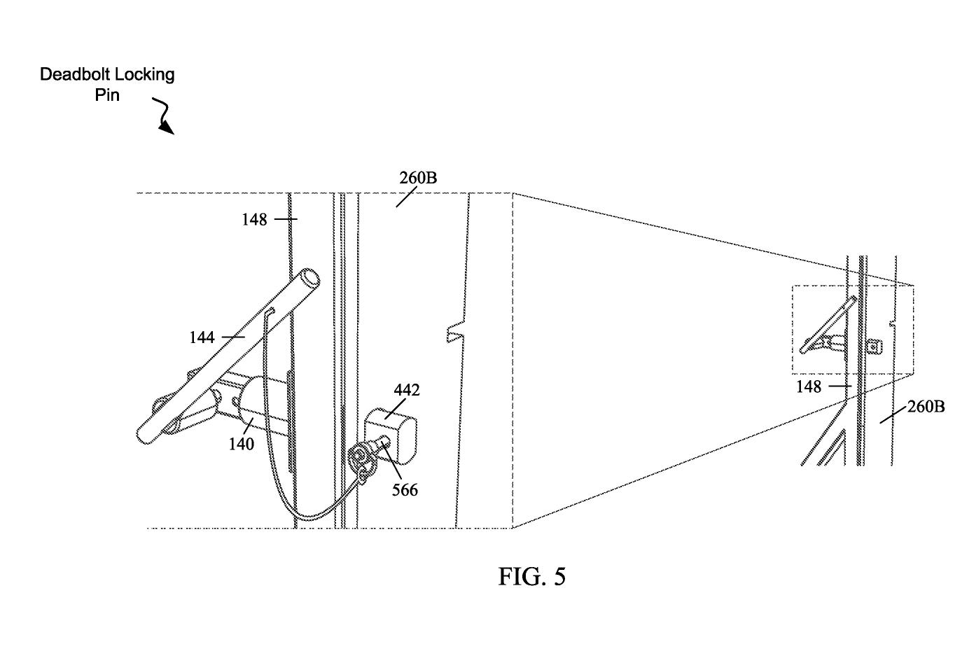

FIG. 5 is an inset drawing consistent with FIG. 4, depicting catch rail 260B and a deadbolt locking pin 566 engaged in a deadbolt 442, according to embodiments. Deadbolt locking pin 566 may be useful to protect against movement of deadbolt 442 to an unlatched position, which may cause disengagement of frame 148 from catch rails (e.g. 260B) and enclosure 100, during a seismic event, according to embodiments. FIG. 5 also depicts handle 144 attached to deadbolt assembly 140. In certain embodiments handle 144 may be removable from the deadbolt assembly 140. Handle 144 may be a lever, Allen wrench, key knob, or other type of actuator that may be manually operated. In some embodiments, handle 144 may be removably attached to deadbolt assembly 140, and may be removed to limit access to the contents of cabinet 100.

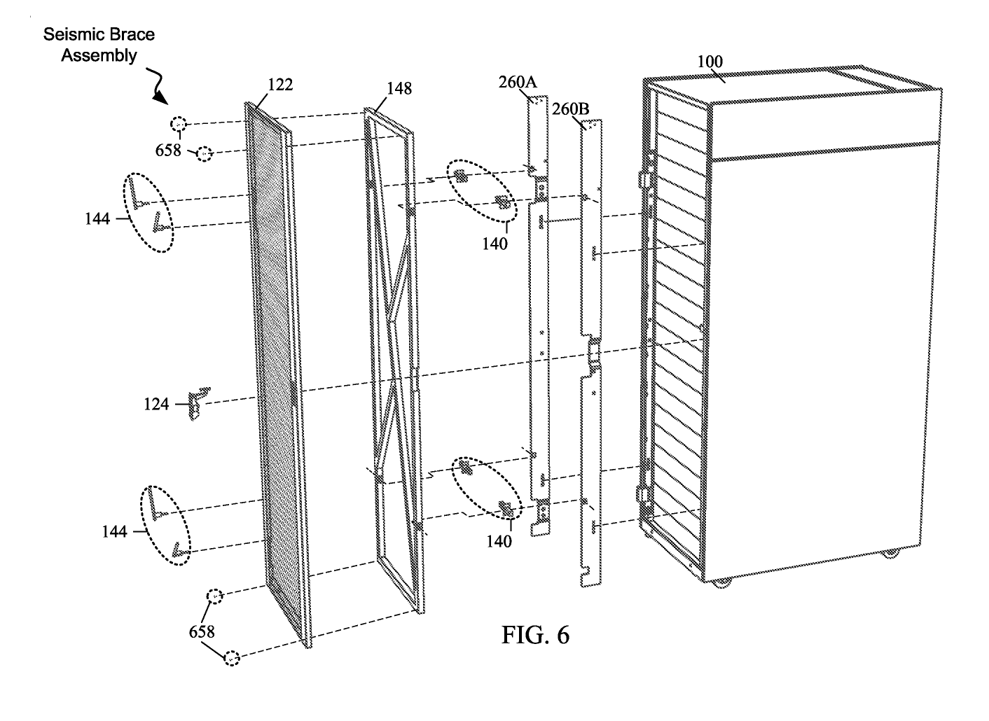

FIG. 6 is an exploded diagram, consistent with the figures, illustrating the integration of a seismic brace assembly into an electronic equipment enclosure 100, according to embodiments. The seismic brace assembly may include catch rails 260A, 260B, deadbolt assemblies 140, handles 144 and frame 148. FIG. 6 depicts relative placements for catch rails 260A, 260B, deadbolt assemblies 140, handles 144, frame 148, fasteners 658 and door 122, consistent with assembly instructions which may be included with a seismic bracing kit. A seismic bracing kit may include a seismic bracing assembly, fasteners for use in attaching a frame 148 to a door 122, and optionally, a door 122 compatible with the frame 148.

Door 122 may be designed with specific features that are compatible with frame 148, including, but not limited to, alignment features such as pins, deadbolt passageways, a cavity to receive frame 148, and holes for the insertion or retention fasteners such as screws or bolts, according to embodiments.

Frame 148 may be designed to meet both specified structural requirements (rigidity) for seismic bracing, and to have a weight within a specified limit. A specified weight limit for frame 148 may be useful in limiting the total weight of the door 122 having an installed seismic brace assembly to a specified 1-person lifting limit, such as an Occupational Safety and Health Administration (OSHA), or National Institute for Occupational Safety and Health (NIOSH), or information technology (IT) industry limit. One such limit, for example, may be 40 pounds; other limits may be observed.

Limiting the weight of door 122 (with installed seismic brace assembly) may facilitate service operations on electronic equipment enclosure 100 to be completed by a single service technician, and may reduce both service costs and a risk of lifting-related injuries by service technicians.

Catch rails 260A, 260B may be secured to the rack 100 with screws or bolts that pass through screw holes formed in the catch rail, and may have structural features such as bends, folds, or recesses that allow attachment to the rack 100, but do not constrain the function of hinges (230A, 230B, FIG. 2) or door latching mechanisms (124, FIG. 2). Catch rails may use mounting points, such as threaded holes, which may already exist in the sidewalls and/or rails of the electronic equipment enclosure 100.

A seismic bracing kit may be useful as an add-on accessory to an electronic equipment enclosure 100, and may provide a cost-effective bracing solution for data centers having existing electronic equipment enclosures 100. A seismic bracing kit, when assembled, may fit within a perimeter of, and attach to a face of, the door 122. A seismic bracing kit may be attached to an electronic equipment enclosure 100, and may remain attached to the enclosure. The rapid engagement and disengagement of the bracing kit with the electronic equipment enclosure 100 may eliminate any requirement for removing the seismic bracing kit, when accessing electronic devices 104 within the rack 100.

In embodiments, the frame 148 may be constructed from hollow, square steel stock. In certain embodiments, frame 148 may be constructed from other materials including but not limited to aluminum, aluminum alloys and composite fiber compositions. Frame 148 material shapes may include but are not limited to hollow square, hollow rectangular, round, solid rectangular, channel stock or angle stock. Frame 148 materials and material shapes may be chosen to meet particular frame rigidity specifications and total door 122 weight requirements.

FIG. 6 depicts a seismic brace assembly for a particular side (e.g., front) of an equipment enclosure 100; a similar seismic brace assembly may be attached to an opposite side of the equipment enclosure 100, for example, a rear side, according to embodiments. An increase in structural integrity of the equipment enclosure 100 may result from the installation of to seismic bracing assemblies.

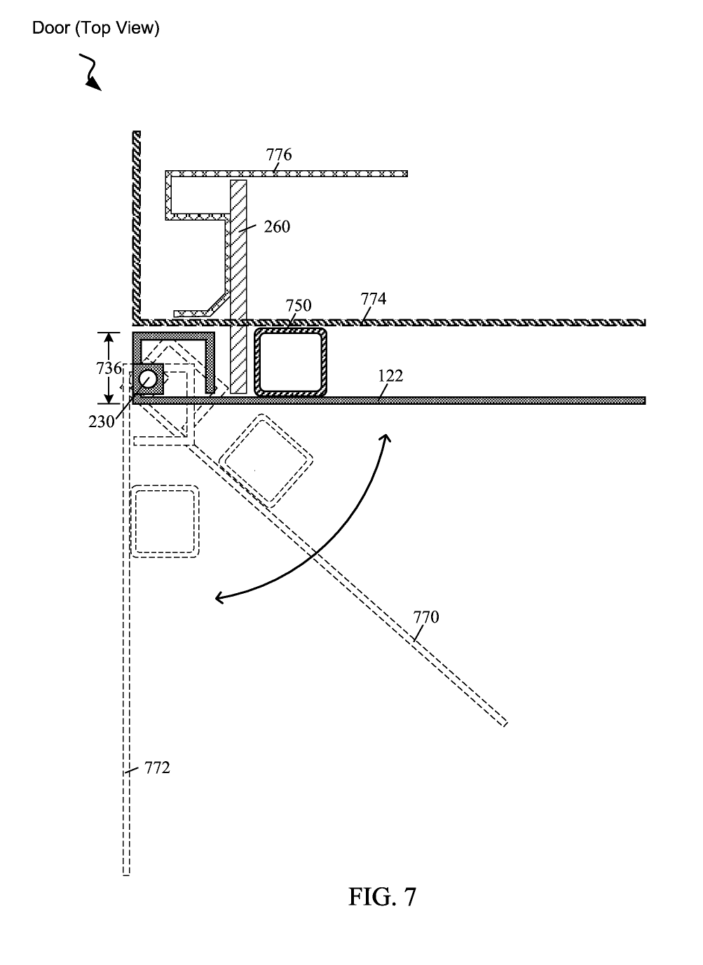

FIG. 7 is a top view, consistent with the figures, of an electronic equipment enclosure door 122, a square stock member 750 of a frame of a seismic brace assembly, and a cabinet outline 774 of enclosure 100, in a closed and two open positions 770, 772, according to embodiments.

Door thickness 736, door height 238 (FIG. 2) and door width 232 (FIG. 2) may define a perimeter of the door 122, and the frame 148 (FIG. 1) may be designed to fit within the perimeter, which may prevent frame 148 (FIG. 1) and square stock member 750 from obstructing the closure of door 122 against the enclosure 100.

Positions 770, 772 illustrate a partially open and fully open position of the door 122, respectively, showing no interference of the square stock member 750 of a seismic brace assembly with the catch rail 260 when door is in open 772, partially open 770, or closed positions. The door 122 may be pivotally attached (hinged) on hinge 230. The catch rail 260 may be configured to attach to Electronic Industries Alliance (EIA) standard rails within the enclosure.

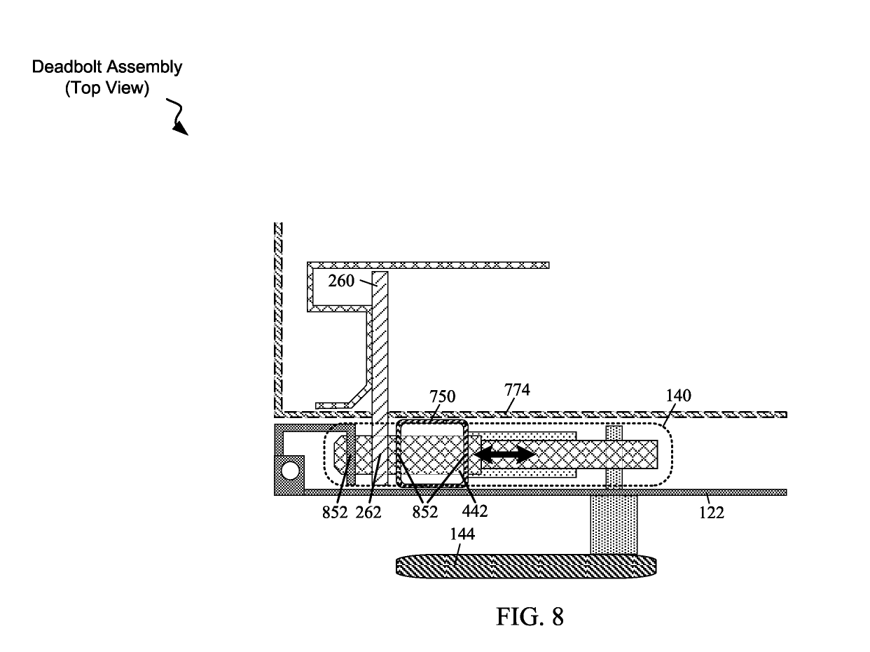

FIG. 8 is a top view, consistent with the figures, of an electronic equipment enclosure door 122, a seismic brace assembly frame member 750, deadbolt assembly 140, deadbolt 442, and a handle 144, in a closed position, according to embodiments. FIG. 8 depicts deadbolt 442 in a latched position, extending through passageways 262, 852 in the catch plate 260, the frame member 750, and the door 122, respectively. The extension of deadbolt 442 through these passageways may be useful in creating a stable mechanical linkage between the seismic brace assembly of the electronic equipment enclosure 100 (FIG. 1).

Deadbolt assembly 140 may include deadbolt 442, linkages between deadbolt 442 and handle 144, and handle 144. The rotation of handle 144 may cause deadbolt 442 to be linearly actuated to a latched position (illustrated) or to an unlatched position, where the deadbolt 442 is retracted and does not pass through the recesses 262, 852 of catch rail 260 or door 122, respectively.

Deadbolt assembly 140 may be attached to frame member 750 of frame 148 (FIG. 1) by a friction-fit insertion into a hole in frame 148, or through the use of screws, bolts or other fasteners. Handle 144 may be fixed to deadbolt assembly 140, for example, by the use of a set-screw, or may be removable from deadbolt assembly 140.

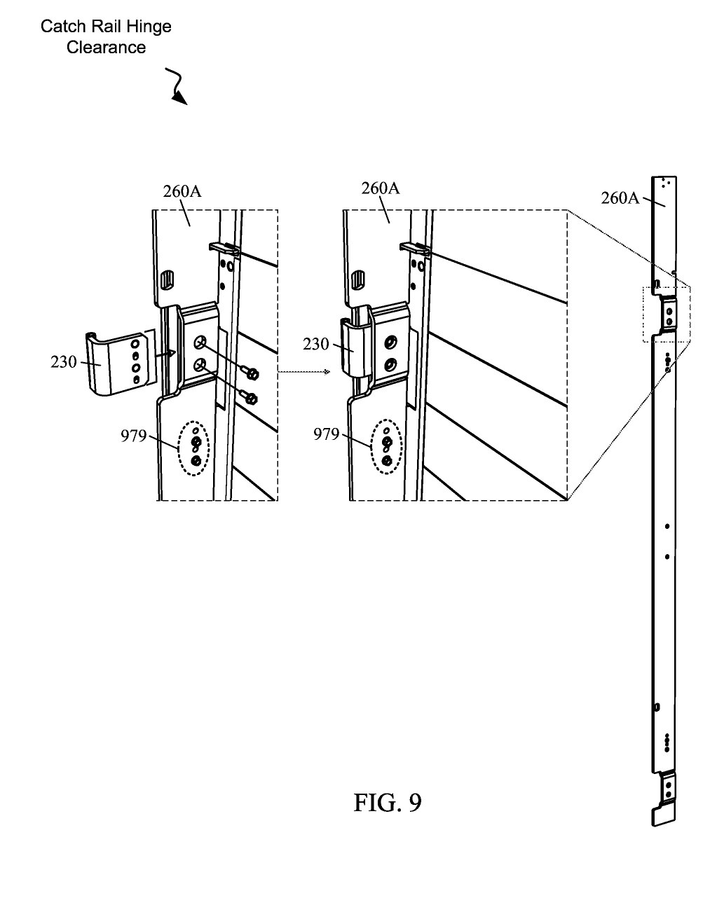

FIG. 9 is an inset drawing, consistent with the figures, depicting a catch rail 260A designed to allow normal operation of an electronic equipment enclosure door hinge 230, according to embodiments. FIG. 9 depicts a catch rail attached to the interior of an electronic equipment enclosure 100. Bends in the catch rail 260A design allow the catch rail to fit over the door hinge 230. Through-holes in the resulting surface may allow tool access for the fastening and/or removal of the hinges without having to remove the catch rail 260A.

The catch rail 260A is configured to allow a door hinge 230 mechanism to function freely; the operation of the hinge 230, and corresponding part on door 122 (FIG. 1) is not hindered in any way by the catch rail 260A. Holes 979 in catch rail 260A that correspond to the existing holes in enclosure 100 may allow catch rail 260A to be attached by bolts or screws to enclosure 100.

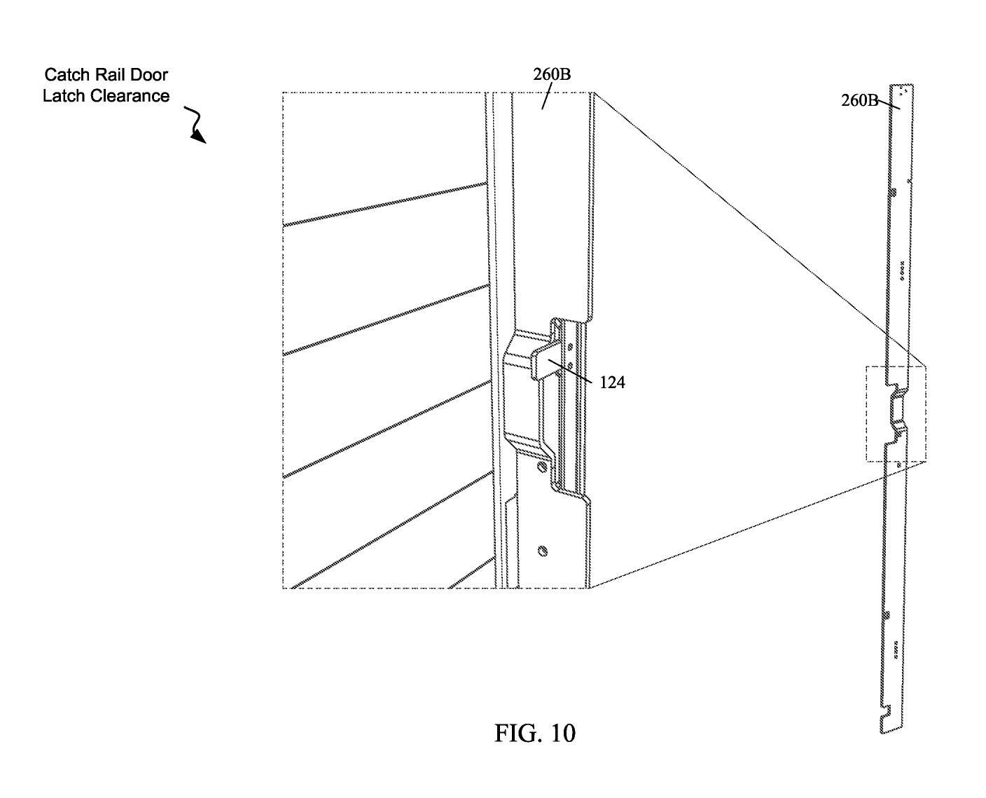

FIG. 10 is an inset drawing, consistent with the figures, depicting a catch rail 260B designed to allow normal operation of an electronic equipment enclosure door latch mechanism 124, according to embodiments. FIG. 10 depicts a catch rail attached to the interior of an electronic equipment enclosure 100. Bends and recesses in the catch rail 260B design may allow the catch rail to fit around the door latch mechanism 124A. Through-holes in the resulting surface may allow tool access for the fastening and/or removal of the hinges without having to remove the catch rail 260B.

The catch rail 260B is configured to allow a door latch mechanism 124A to function freely; the operation of the door latch mechanism 124A, and corresponding part 124 on door 122 (FIG. 1) is not hindered in any way by the catch rail 260B.

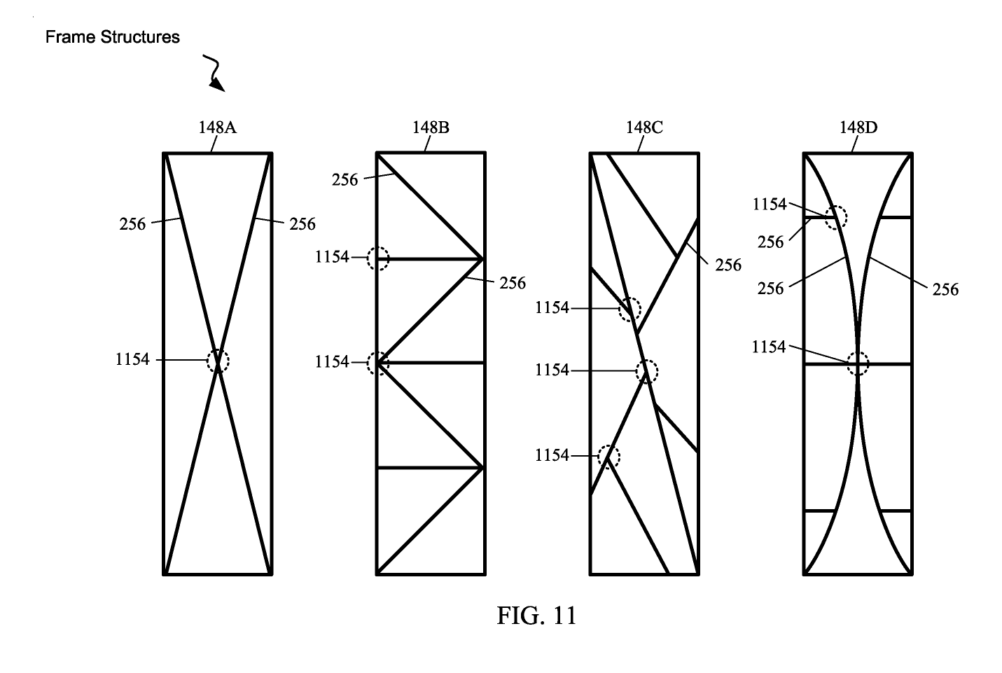

FIG. 11 includes views, consistent with the figures, of 4 seismic brace assembly frame designs 148A, 148B, 148C, 148D, including rigidly attached cross-members 256 and welds 1154, according to embodiments. Seismic brace assembly frames 148A, 148B, 148C, 148D depict four variations of frame designs which may be useful in providing add-on seismic bracing capability for electronic equipment enclosures 100. A particular design may be chosen for an application based on calculated or simulated structural properties, such as resistance to warp, bow, and twist, under certain seismic stress conditions, totaling frame weight and/or frame cost.

Assembly of the frames 148A, 148B, 148C, 148D may include but is not limited to welding, bolting, or other means of rigidly attaching cross-members 256 to the outer, rectangular frame structure. Frames 148A, 148B, 148C, 148D may be attached to door 122 with screws, bolts, or other fastening devices.

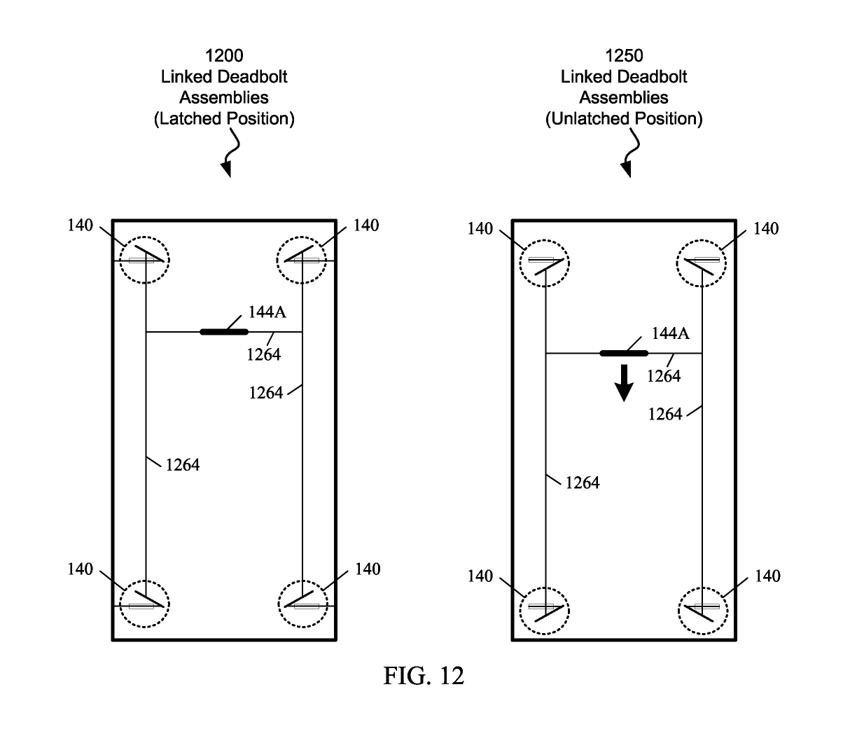

FIG. 12 includes 2 views, consistent with the figures, depicting a plurality of deadbolt assemblies 140 connected through linkages 1264 to a common handle 144A, in a latched position (view 1200) and an unlatched position (view 1250), according to embodiments. The linked deadbolt assemblies depicted may be useful in providing for rapid engagement and disengagement of a plurality of deadbolt assemblies 140 by the movement of a single handle 144A.

View 1200 depicts the linked deadbolt assemblies in a latched position, having the deadbolts of the assemblies extended, which may mechanically engage a frame (148, FIG. 1) with an electronic equipment enclosure 100 (FIG. 1), providing seismic bracing, according to embodiments.

View 1250 depicts the linked deadbolt assemblies in an unlatched position, having the deadbolts of the assemblies retracted, following a downward motion of handle 144A. The position depicted may mechanically disengage a frame (148, FIG. 1) with an electronic equipment enclosure 100 (FIG. 1), according to embodiments. The downwards motion of handle 144A may be translated by linkages 1264 to each of the deadbolt assemblies 140, which may provide simultaneous engagement or disengagement of the deadbolt assemblies 140, according to embodiments.

Certain embodiments may employ a powered actuator, such as an electric motor, solenoid or other electromechanical device to engage or disengage the deadbolt assemblies 140. A powered actuator, in embodiments, may be controlled, for example, by a push-button electric switch.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. A brace assembly for an electronic equipment enclosure that includes a door, the brace assembly comprising:
a frame enclosing a plurality of rigidly attached cross-members, the frame to fit within a perimeter of the door and to attach to a face of the door;
a plurality of deadbolts attached to the frame by a plurality of deadbolt assemblies; and
a plurality of catch rails configured to attach to the electronic equipment enclosure, the catch rails having recesses defined to receive the plurality of deadbolts when the door is in a closed position and the plurality of deadbolts are in a latched position.

2. The brace assembly of claim 1, wherein the frame is attached to an inner face of the door.

3. The brace assembly of claim 1, wherein the frame further comprises passageways defined by positions of the plurality of deadbolts, to allow movement of the plurality of deadbolts through the frame, to be received by the recesses in the catch rails.

4. The brace assembly of claim 1, further comprising a handle operatively attached to a deadbolt assembly of the plurality of deadbolt assemblies, configured to actuate the deadbolt to a latched position and to an unlatched position.

5. The brace assembly of claim 4, wherein the handle is removable from the deadbolt assembly.

6. The brace assembly of claim 4, wherein the handle is located exterior to an outer face of the door.

7. The brace assembly of claim 1, further comprising a handle, connected by linkages to the plurality of deadbolt assemblies, wherein the plurality of deadbolt assemblies may be actuated by movement of the handle.

8. The brace assembly of claim 1, wherein the frame has a planar, rectangular outline.

9. An electronic equipment enclosure, comprising:
a cabinet having:
a first side surface and a second side surface opposite to the first side surface, the first and second side surfaces defining a cavity for housing an electronic component;
a first mounting rail adjacent to the first side surface, and a second mounting rail adjacent to the second side surface, the first and second mounting rails configured to support the electronic component;
a first door opening between a first vertical edge of the first side surface and a first vertical edge of the second side surface, the door opening to receive a door in a closed position;
a first door pivotally attached to a vertical side of the door opening, and having mounting structures to receive a first frame; and
a first brace assembly comprising:
the first frame enclosing a plurality of rigidly attached cross-members, to fit within a perimeter of the first door and to attach to a face of the first door;
a first plurality of deadbolts attached to the first frame by a first plurality of deadbolt assemblies; and
a plurality of catch rails configured to attach to the electronic equipment enclosure at the first and second side surface, the catch rails having recesses defined to receive the first plurality of deadbolts when the first door is in a closed position and the first plurality of deadbolts are in a latched position.

10. The electronic equipment enclosure of claim 9, wherein the first brace assembly has a height and width sufficiently small to fit within the perimeter of the door.

11. The electronic equipment enclosure of claim 10, wherein the perimeter of the door has a thickness, and the brace assembly has a thickness sufficiently small to fit within the thickness of the door.

12. The electronic equipment enclosure of claim 9, wherein the frame and the rigidly attached cross-members are attached to each other by welds.

13. The electronic equipment enclosure of claim 9, wherein the first plurality of deadbolts are configured to engage with upper and lower portions of each of the first and second side surface of the electronic equipment enclosure.

14. The electronic equipment enclosure of claim 13, further comprising a second plurality of deadbolts configured to engage with a top portion and a bottom portion of the electronic equipment enclosure.

15. The electronic equipment enclosure of claim 9, further comprising:
a second door opening opposite to the first door opening;
a second door opposite to the first door, the second door having a second brace assembly comprising a second frame enclosing a plurality of rigidly attached cross-members, to fit within a perimeter of the second door; and
a second plurality of deadbolt assemblies attached to the second frame.

16. A seismic bracing kit for an electronic equipment enclosure that includes a door, the seismic bracing kit comprising:
a frame enclosing a plurality of rigidly attached cross-members and to, when assembled, fit within a perimeter of the door and attach to a face of the door;
a plurality of deadbolts attached to the frame by a plurality of deadbolt assemblies; and
a plurality of catch rails configured to be attached to the electronic equipment enclosure, the catch rails having recesses defined to receive a plurality of deadbolts when the door is in a closed position and the plurality of deadbolts are in a latched position, thereby providing seismic bracing.

17. The seismic bracing kit of claim 16, further comprising fasteners to attach the plurality of deadbolt assemblies to the frame and fasteners to attach the frame to the door.

18. The seismic bracing kit of claim 16, wherein the frame is constructed of hollow, square steel stock.

19. The seismic bracing kit of claim 16, wherein the catch rails are configured to attach to Electronic Industries Alliance (EIA) standard rails within the enclosure.

20. The seismic bracing kit of claim 16, wherein the catch rails are configured to allow a door hinge and a door latch mechanism to function freely.
